(19) United States
(12) Patent Application Publication
(10) Pub. No.: US 2023/0269884 A1
(43) Pub. Date: Aug. 24, 2023

(54) A MANUFACTURING PROCESS TO ENHANCE SURFACE MOUNT SOLDER PAD JOINT FORMATION VIA A LASER SUBTRACTIVE METHOD

(71) Applicant: SHAW, Fraser Murray, Troon (GB)

(72) Inventor: Fraser Murray SHAW, Troon (GB)

(21) Appl. No.: 18/016,525

(22) PCT Filed: Jul. 16, 2021
(86) PCT No.: PCT/GB2021/051834

§ 371 Date: Jan. 17, 2023

(30) Foreign Application Priority Data
Jul. 17, 2020 (GB) 2011045.8

(51) Int. Cl. H05K 3/26; H05K 3/34; H05K 3/00

(52) U.S. Cl. CPC H05K 3/26; H05K 3/3485; H05K 3/3494; H05K 3/0014; H05K 2203/107

(57) ABSTRACT

The present invention relates to the field of electronic assembly for the manufacture of electronic products such as mobile phones, where electronic components such as resistors and capacitors and microprocessors are joined to a bare circuit board to form a complete electronics device and relates to the preparation of attachment locations on a bare circuit board

### FIELD OF THE INVENTION

The present invention relates to the field of electronic assembly for the manufacture of electronic products such as mobile phones, where electronic components such as resistors and capacitors and microprocessors are joined to a bare circuit board to form a complete electronics device. The invention specifically relates to the preparation of joint locations on a bare circuit board.

### BACKGROUND OF THE INVENTION

In the field of electronic assembly, there is a continual need to make complex electronic circuits comprising of a variety of components like resistors, capacitors, and microprocessors interconnected by a passive connection medium normally a “bare” circuit board. These boards are often manufactured remotely from the electronic components themselves. The purpose of the circuit board is to make electrical pathways between the devices, in order to facilitate the working of the entire electronic product.

It is usual for the connection to be made via a copper pathway formed on a circuit board between the devices. The electronic devices must be electrically and mechanically connected to the copper pathway by means of a joint. The joint is made by melting a compound of metals having suitable melting point and flow characteristics when molten around the joint. This encapsulates the copper connection of the circuit board and the electronic component connection such that an inter metallic whole is made with excellent electrical conduction and mechanical strength, This process is known as soldering.

Copper is an excellent conductor of electricity; however, it is also greatly changed by atmospheric air and in its natural state forms a variety of copper oxides very quickly when exposed to air or oxygen. Whilst Natural copper is an excellent surface to join to, using a variety of metallic compounds that can form an inter metallic joint between the component termination and the copper connection of the circuit board, Oxidised copper in comparison is not a good surface to join to. In a normal circuit board assembly, there is a need to protect the copper joint of the circuit board to prevent oxidisation in the time between bare circuit board manufacture and circuit board assembly. There are a variety of ways to protect the copper pad on its journey from manufacture to final assembly, but all come at some cost and all increase the complexity of the final inter metallic bond between electronic component and circuit board. For example, metals such as gold are plated over the copper connection to protect it before connection.

During the process of joining a device connection to a circuit board there is a need to further remove any contaminants from the surface of the copper to promote joint integrity. It is normal for an electronic joint to be made using a compound of metals and fluxes.

Fluxes are compounds that become active at elevated temperatures in order to remove oxides and other contaminants prior to the formation of an inter metallic joint between the circuit board and the electronic component. Usually referred to as “solder” the medium that facilitates the joint can be a wire or a paste.

High volume electronic board production is largely executed by way of “surface mounting” one or more devices on a circuit board. The circuit board has printed on it a solder paste using a precision mask and screen printer. The solder paste deposit is then ready to accept a device connection point when placed upon it. After device placement, the board with the devices placed upon the solder paste deposits, is passed through a reflow oven where first the temperature is raised to the point at which the flux becomes active to facilitate the removal of contaminants and oxides and to prepare the circuit board connection for soldering, then the temperature is raised beyond the melting point of the solder compound metals which will flow into and around the joint to make the desired connection.

The current process for making the most basic Printed Circuit Board (PCB), including pads to be soldered according to the prior art is as follows (many more complex steps are required for the manufacture of the most sophisticated printed circuit boards but the formation and treatment of the pads to be soldered remains the same):

1. Circuit board construction is based on a copper/glass reinforced plastic laminate such as FR4 or a copper/polyamide laminate.
2. A photomechanical process is used to add an etch resist pattern to the base material.
3. A chemical etch is used to selectively remove copper from the base material whereby pads and associated connections are formed then the etch resist is removed leaving only copper and laminate . Alternatively to steps 2 and 3, a laser process may be used to selectively remove copper.
4. A solder mask is added to permanently protect all areas not to be soldered.
5. All pads that are not covered in solder mask and are thereby exposed, are coated with one or more protective layers e.g. plated ENIG (Electroless nickel immersion gold) or OSP (Organic Solderability Preservative).
6. The completed boards are packaged for protection and transported to an electronic assembly facility.
7. When production of an electronic assembly begins the bare circuit boards are unpacked and loaded on to a stacker at the start of and electronic assembly production line.
8. Often an automatic bare circuit board cleaner is used as the first stage in an electronic assembly automated production line—note this cleaning process will only remove dust and environmental debris: it will not remove any metal oxides present.
9. Next an automated, high precision screen printer is used to screen print the pads to be soldered with exact volumes of solder paste deposited on each connection pad as desired according to the specifications laid down by industry bodies and/or component manufacturers.
10. After screen printing, a component placement machine is used to automatically place electronic components exactly on to the screen printed solder paste deposits. This paste is by design tacky, and will hold the component in place ready for transport into the reflow oven.
11. The assembly line then automatically passes the circuit boards with components as an assembly, through the reflow oven whereby the solder paste is melted and recast forming the solder joints which connect the components both electrically and mechanically to the bare circuit board
12. The assembly is now complete and is ready to be tested.

This is a lengthy process which can be wasteful of precious metals, and thus expensive to the manufacturer and also bad for the environment. The process takes a lot of time as there are so many steps.

There is a need to both protect a copper joint from oxidisation and to promote an inter metallic solder joint. Or it may be desirable to mitigate oxidation formation in order to promote an inter metallic solder joint.

There is also a need to provide a more efficient process for preparing a PCB which does not have a protective coating. Additionally there is a need to provide a more efficient process for cleaning and re-shaping/re-surfacing structuring pads on a PCB which has not been coated by a protective layer.

For the above reasons, there remains a need to address or mitigate at least one or more of the aforementioned problems.

### SUMMARY OF THE INVENTION

According to a first aspect of the present invention there is provided a means to both remove all contaminants and oxidisation from a circuit board joint land which is uncoated and increase the surface area of the connection pad to improve the integrity of the joint land by means of laser irradiation. This may be done by the laser removing any surface contaminants and oxides. Further to this, the laser may also change the surface shape of the copper board land.

According to another aspect of the present invention, there is provided a method of producing a printed circuit board (PCB) without adding a protective layer to the areas to be soldered, the method comprising the steps of:
preparing the PCB base material;
etching a resistance pattern to the base material;
adding a solder mask to permanently protect areas of the PCB which are not to be soldered;
allowing the PCB connection pads not covered by solder mask, to passivate naturally;
selective laser cleaning and surface structuring of the PCB to be soldered;
screen print pads with solder paste;
place electronic components on the circuit board; and
pass assembly through reflow oven to form permanent solder joints between the bare circuit board and the electronic components to be assembled.

The PCB may include outer layers made up of connecting tracks and device connection pad areas. All of these features are made in copper or copper alloy via etching or laser processing.

The surface of the circuit board land to be connected to an electronic device is exposed to laser radiation by means of a series of one or more laser emissions applied to the surface of the copper land. The laser emissions have sufficient energy to ablate or remove any surface contaminants and copper oxidisation present on the circuit board land, thereby removing any contaminants and oxides. The laser emissions also have sufficient energy to ablate small volumes of the copper material, such that the surface structure of the material is itself altered. The surface of the copper land can be altered in a manner that increases the surface area of the copper. Increasing surface area of the copper land will improve the release of solder paste from the printing stencil during the screen printing process, greatly improving screen printing yields and will improved the mechanical strength of the solder joint after soldering.

The laser used in this invention may be of any wavelength and be applied to the circuit board land at any level of energy in such combination that is capable of coupling with the circuit board land in manner that may raise the energy of the material so irradiated in a controlled way that causes areas of the surface of the copper land on the circuit board to change state and thereby be moved or removed, resulting in a change of the topography of the copper surface.

The laser used in this invention may be of any wavelength and be applied to the screen at any level of energy in such combination that is capable of coupling with oxides and contaminants such as oil and dirt in a manner that will cause them to change state with sufficient energy to cause such contaminants and oxides to be removed from the surface of the copper.

By using this process, the following advantages are realised; a circuit board connection land may need no or reduced protection from the elements between manufacture and use in a circuit board assembly and may simply be a bare copper surface that can be left to oxidise naturally. Alternatively, a low-cost material may be used to protect the connection land, such that it may be easily removed using laser radiation as part of the preparation process.

The screen-printing process will be improved by achieving a more uniform and more wettable and higher surface area on the copper land to be printed on. The cost of a circuit board will be reduced by removing the need for expensive protective coatings normally added to a circuit board connection land, such as gold plating or may facilitate the replacement of expensive metallic protections, by inexpensive non-metallic coatings easily removed by the laser process.

The integrity of a solder joint formed after laser preparation of the circuit board land will be greatly enhanced by way of improved screen printing.

Other forms of circuit board cleaning such as tacky roller preparation will no longer be required.

The solder paste compound used to form the inter metallic solder joint may be greatly simplified by the reduced need for flux activity afforded by a contaminant free, wettable circuit board land.

Solder paste shelf life will be greatly enhanced by the use of less active fluxes.

The manufacture of circuit boards will be greatly simplified and more environmentally friendly by way of a reduction in coating processes.

Where a subsequent encapsulation process such as parylene coating is to be used to make an electronic assembly waterproof, as is common in modern mobile phones, it may be possible to prepare even the surfaces of edge connectors used to facilitation the connection of multiple devices and circuit boards which are normally gold plated provided that they are coated with a protective layer after assembly.

The circuit board may not have any passivation layer on pads to be soldered after bare board manufacture or it may have a passivation layer that is robust and yet easy to remove via laser cleaning and structuring. Pads to be soldered may be left to naturally oxidise at the point of PCB manufacture as this process will prepare a pure copper pad for soldering. Some advantages of this are:

1) replaces expensive environmentally harmful plating processes to surface finish bare copper PCB's with laser ablation of oxide residues.
2) a huge reduction in harmful chemicals used in PCB production
3) reduces the cost of bare PCB
4) removes energy requirements from bare PCB manufacture—plating requires energy
5) greatly simplifies PCB handling as no special handling of the PCB will be required
6) removes the need for any other PCB cleaning procedure
7) can be combined with other PCB marking processes such as board batch number marking

Because this laser process perfectly prepares the copper pad making it free of oxides, there is less need for activity in the flux used in solder paste. Reduced flux activity means that solder paste can be more environmentally friendly.

The new process is a pure copper pad process and so removes the following process failure modes that are evident with precious metal coatings:

A. ‘Tin whiskers’ can cause long term failure of any PCB assembly. Inter-metallic layers are a significant contributor to the formation of tin whiskers. By using a structured and cleaned pure copper pad instead of a complex e.g. ENIG finish, Tin whisker formation can be mitigated.
B. ‘Black pad’ is another major defect in electronic assembly that is a direct result of having complex precious metal coatings on soldered surfaces. Black pad occurs when the gold layer on a pad becomes subsumed into the solder exposing the nickel layer and a poor joint results.
C. Second side failure of organic surface preservative layers is another common failure mode. OSP is a non-metallic finish that is designed to be removed easily by flux during reflow. OSP finished boards need to be handled very carefully as the coating is easily damaged. Side one manufacture is generally highly successful, however the first pass through the oven can severely compromise the OSP on side 2 leading to opportunities for oxide growth. Generally manufacturers will process side 2 immediately after side 1 with a minimum time delay, in order to minimise the opportunity for oxide formation problems. This new process, herein described, can be used with or without an OSP layer and ensures no oxides are present for both side 1 and side 2.
D. Generally the biggest source of electronic assembly joint failure are uncontrolled oxides. Oxides can be caused by many forms of mishandling, for example an operator's fingerprint on a pad prior to soldering. By ensuring a single element copper pad free of oxides is presented at the time of soldering, this process inherently removes all major oxide causes of defect.

It is therefore evident that the invention comprises many advantages over the prior art.

The current process according to the prior art is as follows:

1. Circuit board construction is based on a copper/glass reinforced plastic laminate such as FR4 or a copper/polyamide laminate.
2. A photomechanical process is used to add an etch resist pattern to the base material.
3. A chemical etch is used to selectively remove copper from the base material whereby pads and associated connections are formed and then the resist is removed leaving only a copper circuit connecting tracks and lands to be connected to referred to as pads. Alternatively a laser process may be used to selectively remove copper.
4. A solder mask is added to permanently protect all areas not to be soldered.
5. All pads that are not covered in solder mask and are thereby exposed, are coated with one or more protective layers e.g. plated ENIG which leaves a gold finish or OSP which leaves an organic finish.
6. The completed boards are packaged for protection and transported to an electronic assembly facility.
7. When production of an electronic assembly begins, the bare circuit boards are unpacked and loaded on to a stacker at the start of an electronic assembly production line.
8. Often an automatic bare circuit board cleaner is used as the first stage in an electronic assembly automated production line—note this cleaning process will only remove dust and environmental debris it will not remove any metal oxides present.
9. Next an automated, high precision screen printer is used to screen print the pads to be soldered with exact volumes of solder paste deposited on each connection pad as desired according to the specifications laid down by industry bodies and/or component manufacturers.
10. After screen printing a component placement machine is used to automatically place electronic components exactly on to the screen printed solder paste deposits. This paste is designed to be tacky, and will hold the component in place ready for transport into the reflow oven.
11. The assembly line then automatically passes the circuit boards with components as an assembly, through the reflow oven whereby the solder paste is melted and recast forming the solder joints which connect the components both electrically and mechanically to the bare circuit board
12. The assembly is now completed and is ready to be tested.

By contrast the new process is as follows:

1. Circuit board construction is based on a copper/glass reinforced plastic laminate such as FR4 or a copper/polyamide laminate.
2. A photomechanical process is used to add an etch resist pattern to the base material.
3. A chemical etch is used to selectively remove copper from the base material whereby pads and associated connections are formed. Alternatively a laser may be used to selectively remove copper.
4. A solder mask is added to permanently protect all areas not to be soldered.
5. Step 5 is removed—pads are not coated instead they are left to passivate naturally
6. Step 6 is greatly simplified as bare circuit boards no longer need significant protection—transport to electronic assembly as normal
7. When production of an electronic assembly begins the bare circuit boards are unpacked and loaded on to a stacker at the start of and electronic assembly production line.
8. Step 8 is now a selective laser clean and surface structure of all pads to be soldered. This process will remove all oxides and contaminants as well as enhancing print process capability and improving solder joint strength and quality. This process will ensure that black pad and tin whiskers joint failure modes are mitigated in the subsequent solder joints.
9. Next an automated, high precision screen printer is used to screen print the pads to be soldered with exact volumes of solder paste deposited on each connection pad as desired according to the specifications laid down by industry bodies and/or component manufacturers.
10. After screen printing a component placement machine is used to automatically place electronic components exactly on to the screen printed solder paste deposits. This paste is by design to be tacky, and will hold the component in place ready for transport into the reflow oven.
11. The assembly line then automatically passes the circuit boards with components as an assembly, through the reflow oven whereby the solder paste is melted and recast forming the solder joints which connect the components both electrically and mechanically to the bare circuit board
12. The assembly is now completed and is ready to be tested.

As shown, the processes that will change are number 5 and number 8. By using laser subtractive processing at number 8 we can eliminate or simplify the process at number 5. Processes 1 through 6 happen at a PCB production plant. Processes 7 through 12 happen at the electronic assembly plant. These process steps above should not be taken to be limiting, but are to be used as mere examples. By making these changes to the normal prior art process, we can mitigate black pad and tin whiskers joint failure modes subsequent solder joints.

The new process according to the invention will therefore:

1) remove pollutants from the PCB manufacturing process
2) reduce the amount of energy used to manufacture bare PCBs
3) reduce the cost of bare PCBs
4) remove the need for expensive coatings on PCB pads to be soldered.
5) reduce the need for expensive packaging and environmental controls for bare PCBs during transport from PCB manufacture to electronic assembly manufacturing
6) Improve solder paste printing transfer efficiency
7) improve solder paste joint strength
8) Make solder paste more environmentally friendly by reducing the required activity in solder pastes
9) remove the number of inter-metallic layers in a solder joint and thereby reduce incidence of tin whiskers
10) remove the number of inter-metallic layers in a solder joint and thereby reduce incidence of black pad
11) reduce the need for solder paste flux activity thereby removing pollutants and expense from solder paste manufacture and improving solder paste shelf life.
12) improve solder paste wetting across a pad being soldered
13) make electronic assembly products easier to recycle by reducing the number of materials used.

Further optional features disclosed in relation to each aspect of the invention correspond to further optional features of each other aspect of the invention.

### BRIEF DESCRIPTION OF THE DRAWINGS

Non-limiting example embodiments the present invention will now be described with reference to the accompanying drawings in which:

FIG. 1 shows the basic principle of laser structuring to alter surface topography;

FIG. 2 shows the principle of how this preparation technique may be applied in a production process;

FIG. 3 shows a surface mount production line, showing a board loader, a solder paste printer, chip mounters, and reflow soldering;

FIGS. 4-8 show a method of PCB production according to the prior art; and

FIGS. 9-12 show the method according to the present invention.

### DETAILED DESCRIPTION

A description of the figures is given below.

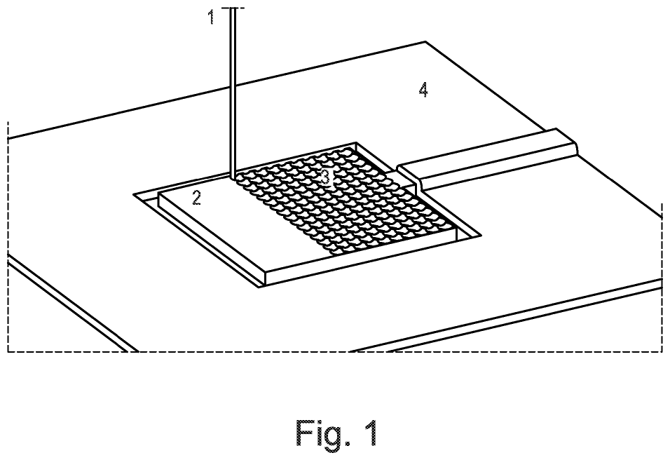

FIG. 1 shows the basic principle of laser structuring. The laser beam is incident on the conductive pad to be soldered to. Usually this is a laser pulse of energy but could be any laser beam having sufficient energy to cause the conductor material, oxides of the conductor material, contaminants of the conductor material, or any chosen conductive material protection layer, to change state with sufficient energy to lift off the surface required to be soldered.

Usually the conductor material is copper. Additionally, the surface may have discrete individual volumes of material removed by each laser pulse or pause in movement such that the surface is no longer largely flat, but instead has a three-dimensional structure created in it. This three-dimensional structure has the effect of increasing the total surface area to be soldered to, thereby increasing the print efficiency of the screen printing process and increasing the mechanical integrity of the solder joint after soldering.

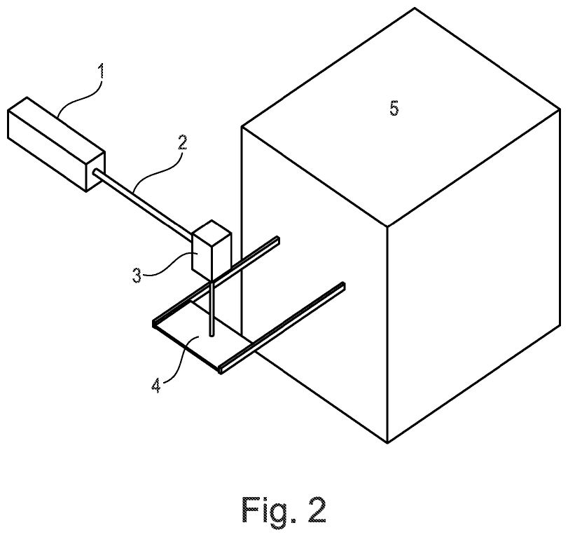

FIG. 2 shows the principle of how this preparation technique may be applied in a production process. The bare circuit board may be introduced to the circuit assembly line without any special storage or preparation. Immediately prior to the screen-printing process, the laser joint preparation process is carried out using a high-speed laser scan to remove oxides, structure, prepare and decontaminate the pads to be screen printed with solder paste and subsequently used to solder surface mount components to the bare board. The laser structuring of the next bare board can be carried out in the time taken to screen print the present board under manufacture in the screen printer.

FIG. 2 shows a Laser (1), a laser beam (2), a laser steering apparatus (3), a bare circuit board (4) and a screen printer (5).

An example of a suitable laser would be a pulsed fibre laser having a wavelength of 1064 nm focused to an area of 3×10⁻¹⁰ M²

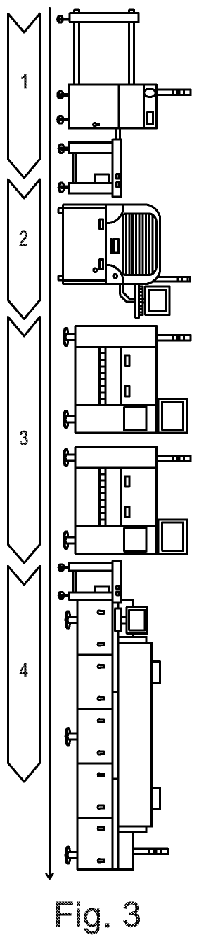

FIG. 3 shows a surface mount production line, showing a board loader 1, a solder paste printer 2, chip mounters 3, and reflow soldering 4. These are standard processes in a production line for circuit boards.

The proposed invention is to be inserted between the solder paste printer 2 and the first of the chip mounters 3. There is therefore a fundamental change to the entire process required. The proposed location of the invention should not be construed to be limiting in this figure, but should be used as an example location. The invention may be used with other components also, other than the ones shown in FIG. 3.

The bare circuit boards must be manufactured differently, i.e. without specialist coatings on the surface mount pads. There is the cost saving and elimination of pollution from this step, however if these boards were to be used without the apparatus according to this invention then it is important to note that the process would no longer work as the joints would fail.

If normal coated pads were used on a circuit board then the apparatus according to the invention could not be used as we might expose surfaces that also could not easily be soldered to. However the apparatus according to the invention could be switched in to a pass through mode or marking mode - where it would be used to mark (an ancillary function) but no pad preparation.

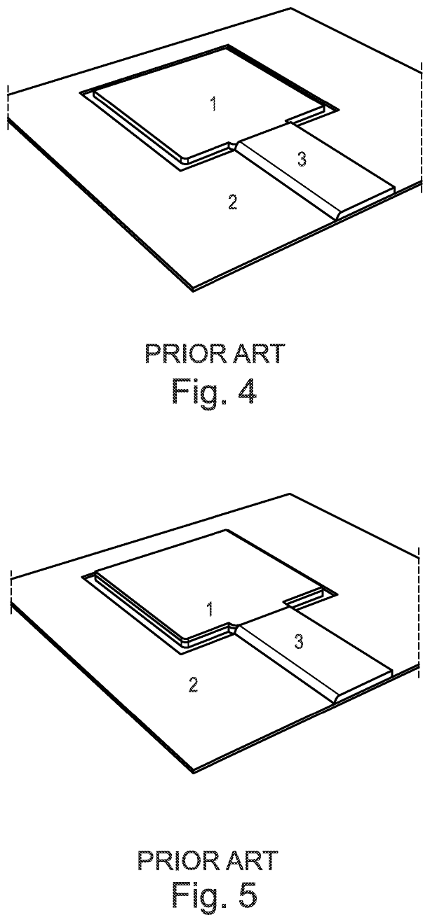

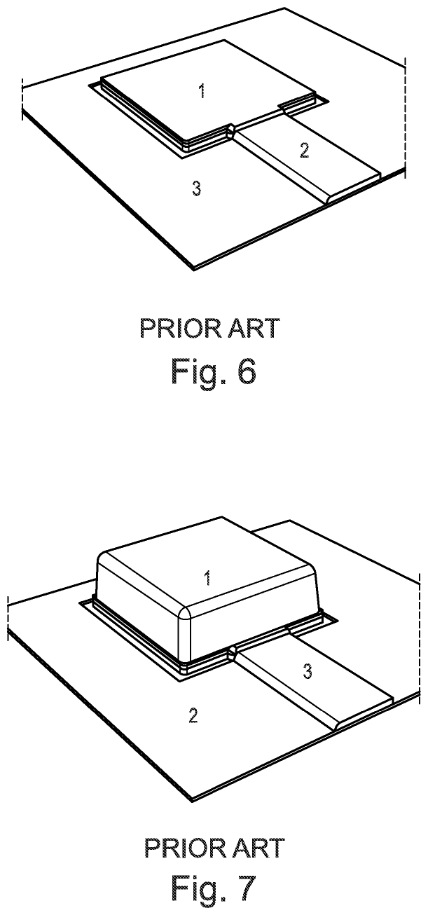

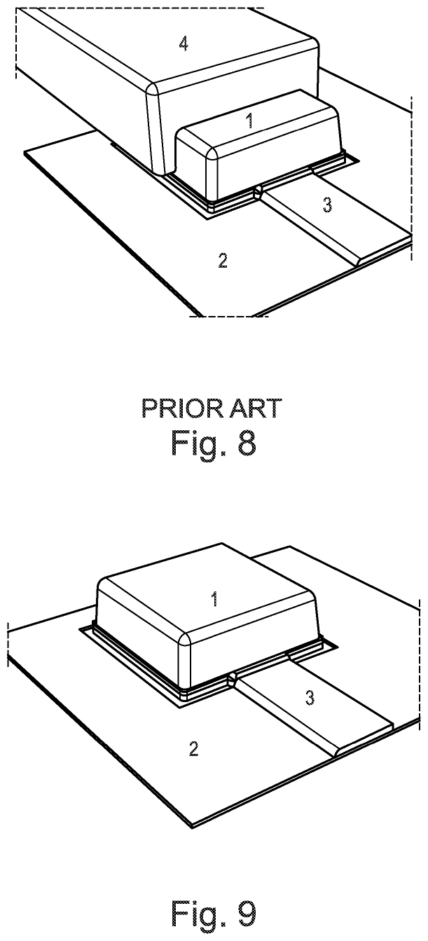

FIGS. 4-8 shows a method of PCB production according to the prior art. FIG. 4 is a simple bare copper pad shown as part of an ENIG process. The copper is shown as 1 in the figure, along with the FR4 coated with a solder mask in 2, and the connection tracks shown with a solder mask in 3. FIG. 5 shows the same pad as in FIG. 4, however the pad is coated with Ni. FIG. 6 is the same pad as in FIG. 5, however the copper and Ni pad has now been coated with Au. As shown in FIG. 7, the pad is then printed with solder paste. Finally, FIG. 8 shows the surface mount component placed on the solder paste, where it is reflowed to form a solder joint. The SMT component placed on the solder paste is shown as ‘4’ in FIG. 8.

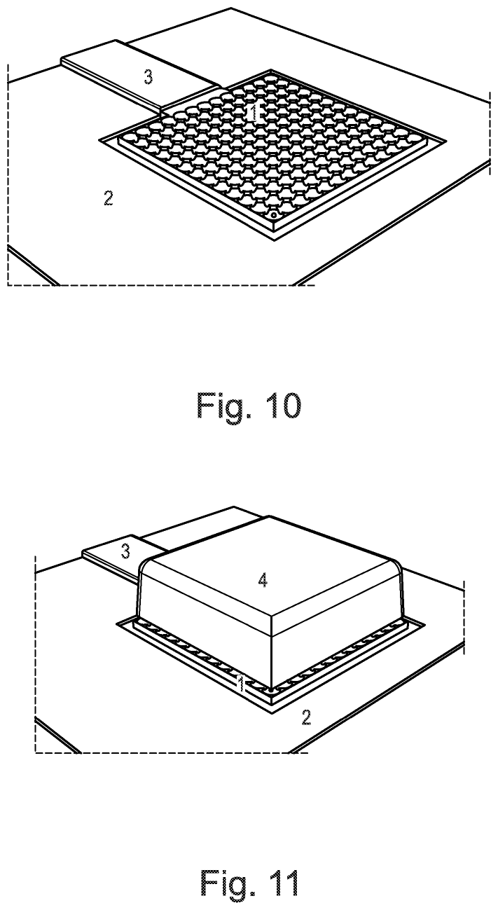

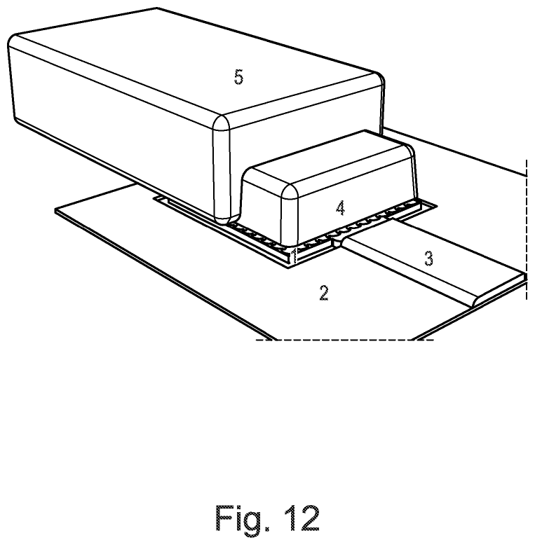

Turning back to the invention, FIG. 9 shows a simple copper pad which is ready for the new laser process according to the invention. FIG. 10 shows the step which takes place just prior to the screen print process, where the laser is used to remove oxides, clean and structure the copper pad. This is shown as the textured surface ‘1’ in FIG. 10. FIG. 11 shows the next step, where the solder paste is printed directly on to the laser cleaned and structured copper. The screen printed solder paste can be seen as item ‘4’ in FIG. 11. FIG. 12 shows the surface mount component ‘5’ placed on the solder paste, before it is reflowed to form the solder joint.

For the present invention to function, the current end-to-end production process must change fundamentally. It is a combination of a change to the circuit board manufacturing process to omit the protective coatings from connection pads, allowing copper to oxidise naturally forming a protective layer of copper oxide, and the laser structuring which is the basis of the invention.

According to the present invention, the copper oxide can be beneficial as a surface protection that is easily removed. Alternatively a low cost pad protection layer may be used provided it may be easily removed by laser.

Having a bare copper pad also enables the invention to structure the surface to improved solder paste printing. Without the simplified PCB—this part will also not work.

The laser emission may be transmitted to the surface of the pad to be soldered in any suitable manner well known to the laser industry. For example the connection pad to be treated may be stationary while the laser energy is applied in one or more bursts using either a moving laser or by the use of steering optics that deflect the laser path in such a way as to control the path of the laser. Alternatively the laser may be stationary whilst the screen is moved under the laser emission path.

Whilst specific embodiments of the present invention have been described above, it will be appreciated that departures from the described embodiments may still fall within the scope of the present invention.

1. A method of producing a printed circuit board (PCB) without adding a protective layer to the areas to be soldered, the method comprising the steps of:
preparing the PCB base material;
etching a circuit board connection pattern in the resistance pattern to the base material;
adding a solder mask to permanently protect areas of the PCB which are not to be soldered;
allowing the PCB pads which are not protected by a solder mask to passivate naturally by the formation of a copper oxide;
selective laser cleaning and surface structuring of the PCB to be soldered;
screen printing pads with solder paste;
placing components on the circuit board; and
passing the circuit board through a reflow oven.

2. A method according to claim 1, wherein the method comprises the further step of changing the surface shape of the PCB with the laser.

3. A method according to claim 1, wherein the base material is made from copper or a copper alloy.

4. A method of removing contaminants and oxidisation by means of laser irradiation from a circuit board joint land to be connected to an electronic device, wherein the method increases the surface area of the connection pad to improve the integrity of the joint land.

5. A method according to claim 4, wherein the laser may also change the surface shape of the copper board land.

6. A method according to claim 4, wherein the surface of the circuit board land to be connected to an electronic device is exposed to laser radiation by means of a series of one or more laser emissions applied to the surface of the copper land.

7. A method according to claim 6, wherein the laser emissions have sufficient energy to ablate or remove any surface contaminants and copper oxidisation present on the circuit board land, thereby removing any contaminants and oxides.

8. A method according to claim 6, wherein the laser emissions also have sufficient energy to ablate small volumes of the copper material, such that the surface structure of the material is itself altered.

9. A method according to claim 6, wherein the surface of the copper land can be altered in a manner that increases the surface area of the copper, thus improving the release of solder paste from the printing stencil during the screen printing process.

10. A method according to claim 6, wherein the laser used is of any wavelength and is applied to the circuit board land at any level of energy in a combination that is capable of coupling with the circuit board land in a manner that changes the energy of the material, thus causing areas of the surface of the copper land on the circuit board to change state and thereby be moved or removed, resulting in a change of the topography of the copper surface.

11. An apparatus for carrying out a method according to claim 1.
